(19) United States
(12) Patent Application Publication
(10) Pub. No.: US 2026/0004862 A1
(43) Pub. Date: Jan. 1, 2026

(54) MERGED MEMORY DIES FOR WAFER-LEVEL TESTING

(71) Applicant: Micron Technology, Inc., Boise, ID (US)

(72) Inventors: Michele Piccardi, Cupertino, CA (US); Kitae Park, Cupertino, CA (US)

(21) Appl. No.: 19/232,384

(22) Filed: Jun. 9, 2025

Related U.S. Application Data
(60) Provisional application No. 63/666,629, filed on Jul. 1, 2024.

(51) Int. Cl. G11C 29/00

(52) U.S. Cl. CPC G11C 29/006

(57) ABSTRACT

A semiconductor wafer includes a plurality of memory dies disposed thereon. The plurality of memory dies are arranged as a plurality of superdies for testing, wherein each of the plurality of superdies comprises two or more of the plurality of memory dies. At least a subset of components of the two or more of the plurality of memory dies in each of the plurality of superdies are electrically shorted together to receive shared test signals from test equipment during the testing.

### RELATED APPLICATIONS

This application claims the benefit of U.S. Provisional Patent Application No. 63/666,629, filed Jul. 1, 2024, the entire contents of which are hereby incorporated by reference herein.

### TECHNICAL FIELD

Embodiments of the disclosure relate generally to memory devices, and more specifically, relate to merged memory dies for wafer-level testing.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating a system for wafer-level testing of memory dies in accordance with some embodiments of the present disclosure.

FIG. 2 is a block diagram illustrating merged memory dies for wafer-level testing in accordance with some embodiments of the present disclosure.

FIG. 3A and FIG. 3B are circuit diagrams illustrating a superpad used with merged memory dies for wafer-level testing in accordance with some embodiments of the present disclosure.

FIG. 4 is a block diagram illustrating analog power components in merged memory dies for wafer-level testing in accordance with some embodiments of the present disclosure.

FIG. 5 is a block diagram illustrating switching of control signals in merged memory dies for wafer-level testing in accordance with some embodiments of the present disclosure.

FIG. 6A illustrates an example computing system that includes a memory sub-system in accordance with some embodiments of the present disclosure.

FIG. 6B is a block diagram of a memory device in communication with a memory sub-system controller of a memory sub-system, in accordance with some embodiments of the present disclosure.

FIG. 7 is a schematic of portions of an array of memory cells as could be used in a memory of the type described with reference to FIG. 6B in accordance with some embodiments of the present disclosure.

FIG. 8 is a flow diagram of an example method of forming merged memory dies for wafer-level testing in accordance with some embodiments of the present disclosure.

FIG. 9 is a block diagram of an example computer system in which embodiments of the present disclosure can operate.

### DETAILED DESCRIPTION

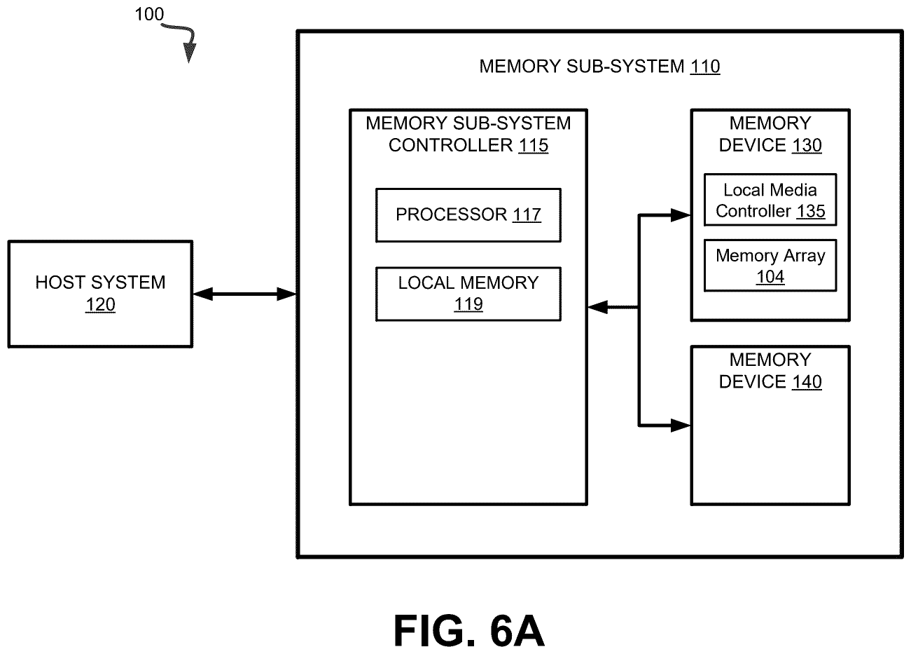

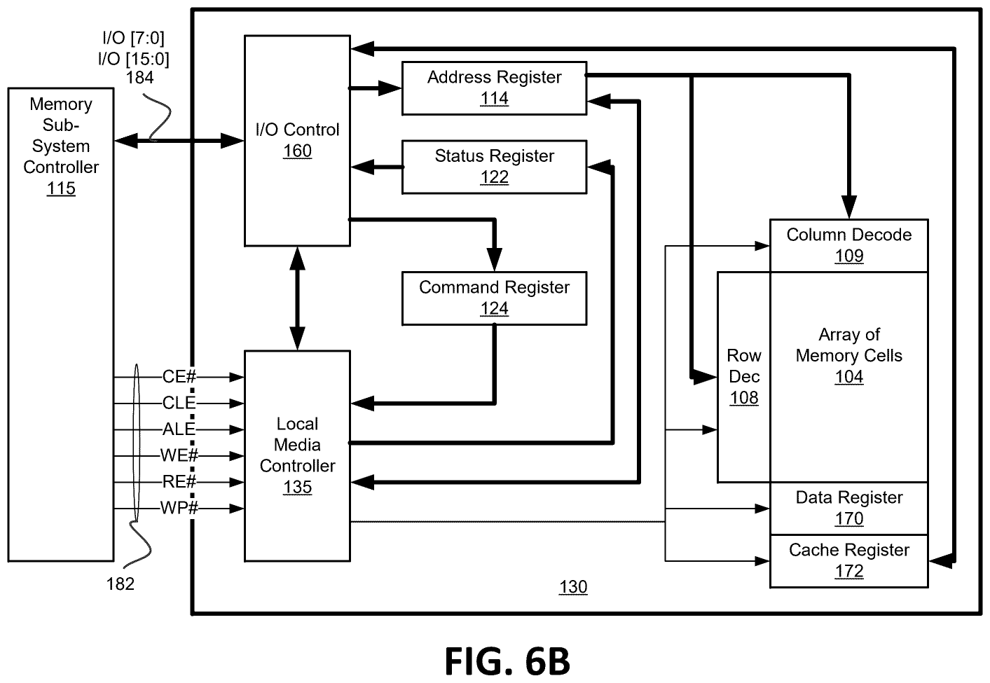

Aspects of the present disclosure are directed to merged memory dies for wafer-level testing. A memory sub-system can be a storage device, a memory module, or a hybrid of a storage device and memory module. Examples of storage devices and memory modules are described below in conjunction with FIG. 6A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

Each memory device can be formed as an individual memory die that includes an array of memory cells and other associated circuitry, such as control logic, analog voltage generators, signal drivers, input/output circuitry (e.g., signal communication pads), etc. A number of individual memory dies can be fabricated together on a silicon wafer. A semiconductor manufacturing process can be used to deposit and pattern multiple layers of materials on the wafer to form the circuitry of the individual memory dies in parallel. Once fabrication is complete, the individual memory dies can be tested and subsequently separated from one another for utilization in separate memory sub-systems.

In order to decrease fabrication time and cost, it is desirable to maximize the number of memory dies that are included on each wafer (i.e., the number of dies per wafer (DPW)). In addition, as manufacturing processes improve, the size of each die decreases, which advantageously increases the number of dies that can be formed on each wafer. With increases in the number of dies per wafer, however, new challenges associated with testing the memory dies arise. In a conventional testing setup, test equipment (e.g., a probe card) includes a number of micro-probes (i.e., needles) that physically contact (i.e., touch down with) the metal signal communication pads on the memory die to provide power signals, control signals, and data signals, and to collect data and other measurements. The test equipment can analyze the collected data to evaluate the functionality of the memory die. Often the test equipment will be arranged to test all of the dies, or at least a subset of the dies, on the wafer in parallel by having one or more micro-probes arranged to contact the signal communication pads of multiple dies concurrently, to provide and collect respective test signals. With smaller memory dies and more dies per wafer, the spacing between the memory dies is decreased which makes alignment of the micro-probes with the corresponding signal communication pads more difficult. For example, physical size constraints of the probe card and the spacing between micro-probes may decrease the percentage of memory dies on the wafer that can be tested concurrently. As a result, multiple sequential test cycles may be needed, such as every other die being tested in a first cycle and the remaining dies being tested in a second cycle. This increases the overall testing time, complexity of the testing process, and cost associated with memory die fabrication.

Aspects of the present disclosure address the above and other deficiencies by merging memory dies for wafer-level testing. In one embodiment, two or more memory dies (e.g., a pair of memory dies) are merged to form a “superdie” on the silicon wafer such that each of the memory dies in the superdie can be tested concurrently using only a single set of micro-probes. For example, while each individual memory die has a separate set of signal communication pads, certain components of the individual memory dies can be physically shorted together so that power signals, control signals, and data signals from the test equipment can be provided to the signal communication pads on only one of the individual memory die (i.e., a primary die), but shared with one or more other memory dies (i.e., a secondary die). In one embodiment, certain portions of the power grids and the signal busses used to convey control signals from respective control logic components to respective memory arrays on each memory die are shorted together in order to share corresponding signals. In this manner, the control logic on the secondary die can be disabled during testing and the control logic on the primary die can be used to control testing operations for the entire superdie. After testing is complete, the individual memory dies can optionally be separated, such as by severing the physical shorts between memory dies, so that the memory dies can be included in separate memory sub-systems.

Advantages of this approach include, but are not limited to, improved performance for memory die fabrication and wafer-level testing. In this manner, individual die size can be reduced, as well as the spacing between individual dies on the wafer, which increases overall yield, while still permitting wafer-level testing to be completed. Such wafer-level testing can be performed more efficiently (i.e., with a lower testing time and using fewer pieces of test equipment), which reduces the overall cost of memory die fabrication.

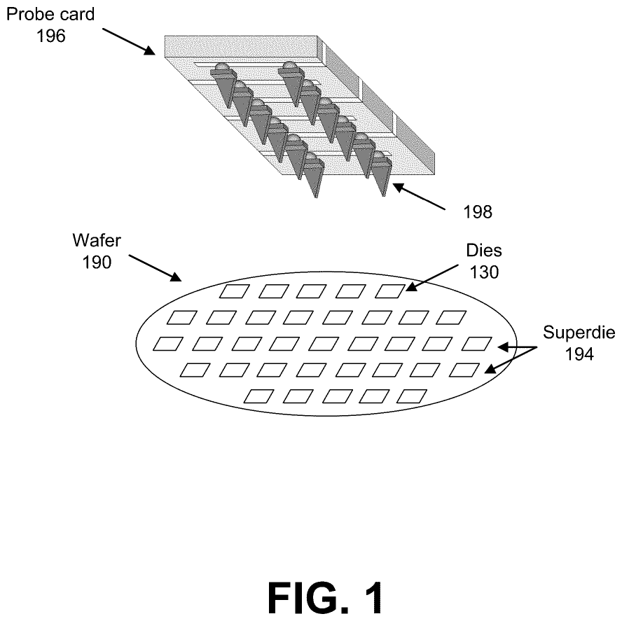

FIG. 1 is a diagram illustrating a system for wafer-level testing of memory dies in accordance with some embodiments of the present disclosure. In a semiconductor fabrication process performed using the system, a number of identical integrated circuits, such as memory dies 130, are formed as individual semiconductor dies on a semiconductor wafer 190 or other bulk semiconductor substrate. The number of memory dies 130 on wafer 190 may number in the hundreds, or even thousands of individual semiconductor dies which are generally repeated across the wafer 190 in a two-dimensional array. In some embodiments, two or more individual memory dies 130 can be at least temporarily merged together to form a “superdie,” such as superdie 194.

Once the memory dies 130 and/or superdies 194 are fabricated at semiconductor die locations on the semiconductor wafer 190, the memory dies 130 and/or superdies 194 can be tested to determine which dies are at least nominally functional. In some embodiments, the testing can be performed by test equipment, such as probe card 196, which can test each memory die and/or superdie 194 individually. The probing of individual semiconductor dies may be performed by probe card 196 while the dies are still formatted together on wafer 190. For example, probe card 196 can contact respective signal communication pads on the memory dies 130 and/or superdies 194 with respective micro-probes 198. Certain probe tests include each die be probed in order to determine the correct and acceptable functionality of the die. As will be described in more detail herein, the multiple memory dies that form each superdie 194 can be tested concurrently using only a single set of micro-probes 198. As such, performing wafer-level testing on the superdies 194 can significantly decrease the overall testing time, expense, and resource utilization compared to testing each individual memory die 130 separately.

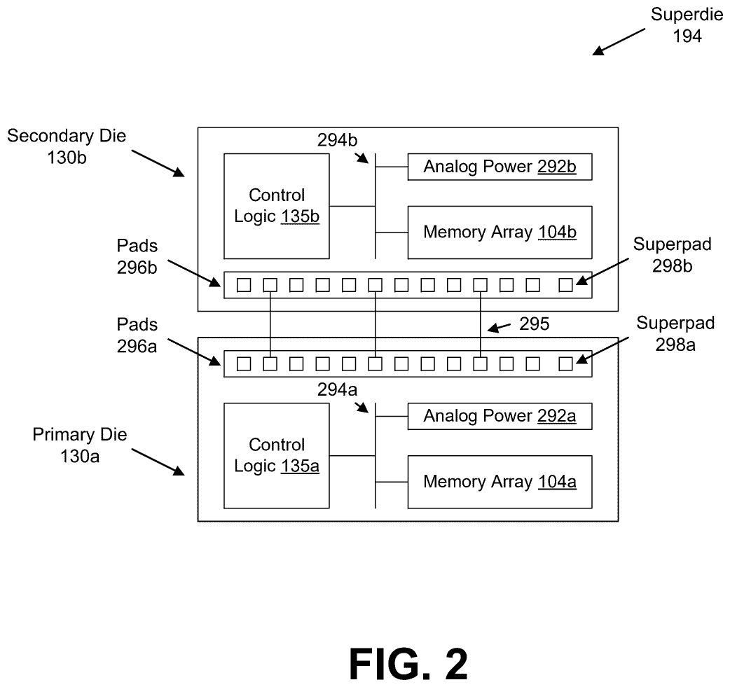

FIG. 2 is a block diagram illustrating merged memory dies for wafer-level testing in accordance with some embodiments of the present disclosure. In one embodiment, a primary memory die 130a and a secondary die 130b have been at least temporarily merged to form a superdie 194. As described, the individual memory dies 130a and 130b that form superdie 194 can be tested concurrently using only a single set of micro-probes 198. Although superdie 194 is illustrated as including only two individual memory dies, it should be understood that in other embodiment, some other number of individual memory dies can be merged to form a superdie 194.

Each of primary memory die 130a and secondary memory die 130b includes a control logic component 135a, 135b, a memory array 104a, 104b, and an analog power component 292a, 292b, which are connected to each other within each memory die by a communication bus 294a, 294b. In addition, each of memory dies 130a and 130b can include a set of signal communication pads 296a, 296b which provide an interface for transmitting signals between the components of each respective memory die and any off-chip circuitry, such as probe card 196. For example, the micro-probes 198 of probe card 196 can contact any of the signal communication pads to provide power signals, control signals, and data signals to the memory dies 130a and 130b, and to collect data and other measurements from the memory dies 130a and 130b. It should be understood that memory dies 130a and 130b may include different and/or additional components, which are not shown here. In general, memory dies 130a and 130b are identical such that they include the same internal components. In some cases, the arrangement and orientation of those components can be identical, however, in other cases, the arrangement and orientation of those components can vary from die to die. For example, as illustrated in FIG. 2, the set of communication pads 296a is oriented at the top of primary die 130a, while the set of communication pads 296b is oriented at the bottom of secondary die 130b. In other embodiments, the sets of communication pads can be at the top of each respective memory die, at the bottom of each respective memory die, or at opposite sides of each respective memory die.

In one embodiment, one or more communication pads in the respective sets of communication pads 296a, 296b can be electrically shorted 295 to one another so that signals can be shared between the pads. For example, communication pads that are coupled to respective power grids of the memory dies 130a and 130b and configured to receive external power supply signals (e.g., from probe card 196) can be electrically shorted 295 such that the power supply signals are shared between the respective power grids. Similarly, communication pads that are coupled to the respective communication busses 294a, 294b and configured to receive external data signals (e.g., from probe card 196) can be electrically shorted 295 such that the data signals are shared between the respective communication busses 294a, 294b. Other communication pads in the sets of communication pads 296a, 296b can be similarly shorted. In this manner, both memory dies 130a and 130b that form superdie 194 can be tested concurrently using only a single set of micro-probes 198.

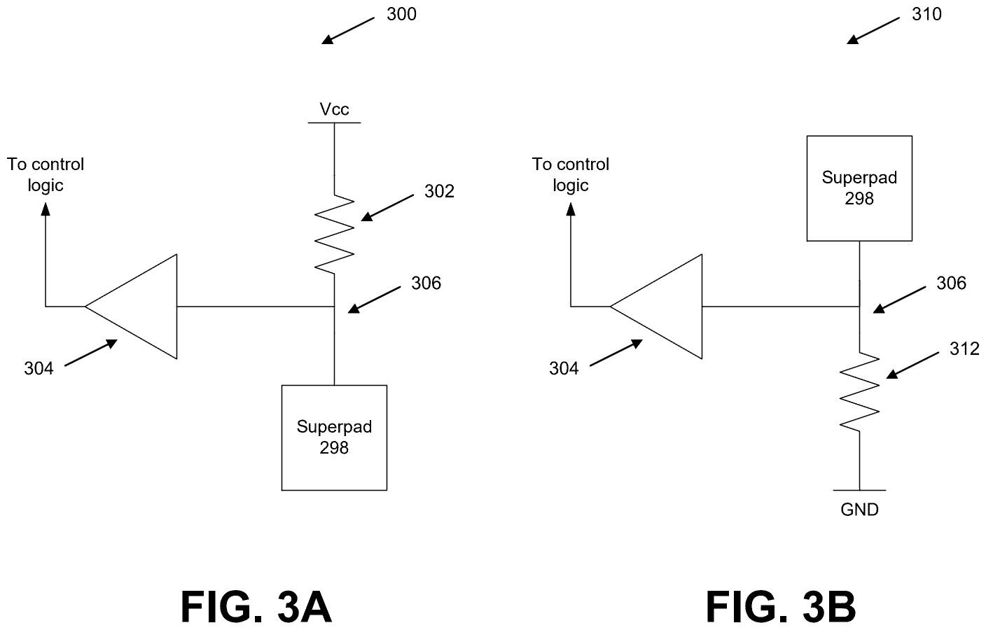

The designation of primary memory die 130a as compared to secondary memory die 130b is indicative of which memory die is physically contacted by micro-probes 198. For example, in order to test superdie 194, the micro-probes 198 can contact the set of communication pads 296a of primary memory die 130a. Any signals received by primary memory die 130a at communication pads 296a can be transferred to communication pads 296b of secondary memory die 130b via the electrical shorts 295. Similarly, any data, measurements, or other test information that is generated by secondary die 130b can be transferred to communication pads 296a of primary die 130a, and ultimately to probe card 196, via the electrical shorts 295. In one embodiment, each set of communication pads 296a, 296b includes a designated superpad 298a, 298b which can be used to indicate which memory die is the primary memory die 130a and which is the secondary memory die 130b, as described in more detail below with respect to FIG. 3A and FIG. 3B. Certain components in both memory dies 130a and 130b may remain active during the testing process (e.g., memory arrays 104a, 104b, analog power components 292a, 292b, and communication busses 294a, 294b) while certain components of secondary memory die 130b are deactivated during the testing process (e.g., control logic component 135b) while testing is performed by the corresponding component in primary memory die 130a.

FIG. 3A is a circuit diagram illustrating a superpad used with merged memory dies for wafer-level testing in accordance with some embodiments of the present disclosure. Circuit 300 includes superpad 298, which may be representative of either superpad 298a or 298b of FIG. 2, a pull up resistor 302, and a low-speed input buffer 304. The pull-up resistor 302 is coupled between a voltage supply source (Vcc) and the superpad 298, while the low-speed input buffer 304 is connected to a sampling node 306 between the pull-up resistor 302 and the superpad 298.

As described above, each of primary memory die 130a and secondary memory die 130b can include a respective superpad 298, as well as associated circuitry 300. During testing, probe card 196 can apply a ground voltage signal to the superpad 298a on the primary memory die 130a (e.g., via one of micro-probes 198), while no signal is applied to the superpad 298b on the secondary memory die. Circuit 300 can be used by the respective control logic components 135a, 135b to determine whether a given memory die is the primary memory die 130a, and thus that the control logic component 135a should remain active during testing, or the secondary memory die 130b, and thus that the control logic component 135b should be deactivated during testing.

In one embodiment, when no signal is applied to the superpad 298, the pull-up resistor will pull the voltage at sampling node 306 up to the Vcc level (e.g., 1.2 volts). The voltage at sampling node 306 is detected at the input of low-speed input buffer 304, which can transmit a corresponding logical value (e.g., a logical ‘1’) to the respective control logic on the memory die. The control logic can decipher the logical value as indicative of the memory die being the secondary memory die 130b, and thus the control logic 135b can be deactivated for the remainder of the testing process. Conversely, when a ground signal is applied to the superpad 298, voltage at sampling node 306 will be at or near the ground level (e.g., 0 volts). The voltage at sampling node 306 is detected at the input of low-speed input buffer 304, which can transmit a corresponding logical value (e.g., a logical ‘0’) to the respective control logic on the memory die. The control logic can decipher the logical value as indicative of the memory die being the primary memory die 130a, and thus the control logic 135a can remain active for the remainder of the testing process.

In another embodiment, as illustrated in FIG. 3B, instead of the pull-up resistor 302, the circuit 310 can include a pull-down resistor 312 coupled between the superpad 298 and a ground supply (GND). In such an implementation, when no signal is applied to the superpad 298, the pull-down resistor 312 will pull the voltage at sampling node 306 down to the ground level (e.g., 0 volts). The voltage at sampling node 306 is detected at the input of low-speed input buffer 304, which can transmit a corresponding logical value (e.g., a logical ‘0’) to the respective control logic on the memory die. The control logic can decipher the logical value as indicative of the memory die being the secondary memory die 130b, and thus the control logic 135b can be deactivated for the remainder of the testing process. Conversely, when a higher voltage signal is applied to the superpad 298, voltage at sampling node 306 will be at or near the that voltage level (e.g., 1.2 volts). The voltage at sampling node 306 is detected at the input of low-speed input buffer 304, which can transmit a corresponding logical value (e.g., a logical ‘1’) to the respective control logic on the memory die. The control logic can decipher the logical value as indicative of the memory die being the primary memory die 130a, and thus the control logic 135a can remain active for the remainder of the testing process

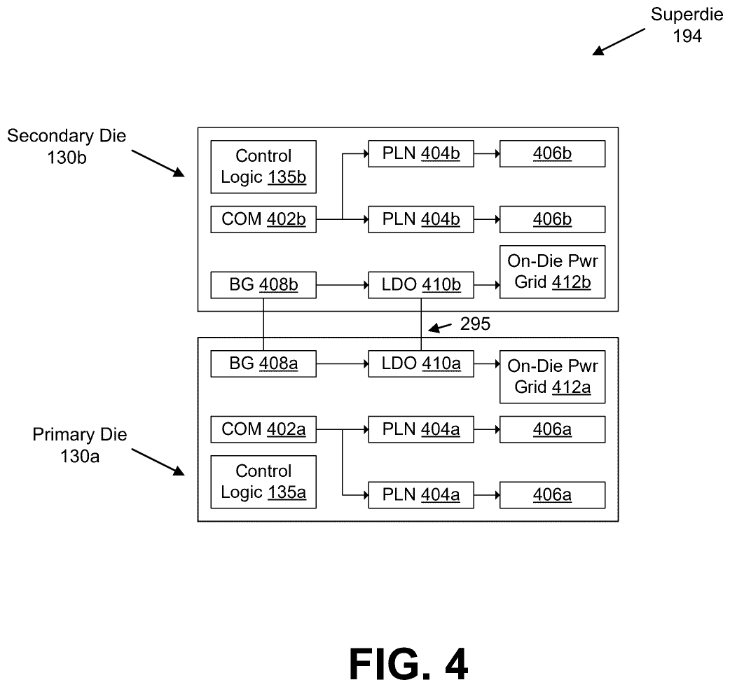

FIG. 4 is a block diagram illustrating analog power components in merged memory dies for wafer-level testing in accordance with some embodiments of the present disclosure. In one embodiment, primary memory die 130a and secondary memory die 130b have been at least temporarily merged to form superdie 194. As described above, each of primary memory die 130a and secondary memory die 130b includes a control logic component 135a, 135b, analog power components, and potentially other components which are not shown. The analog power components are shown in more detail in FIG. 4. For example, the analog power components in each memory die can include a common voltage generator (COM) 402a, 402b that generates a common supply voltage for all planes of the memory die, and individual plane level circuits (PLN) 404a, 404b corresponding to each respective plane of the memory die, where each PLN 404a, 404b is associated with a respective set of data line drivers and a page buffer, collectively 406a, 406b, for the respective plane. In addition, the analog power components in each memory die can include a low voltage and bandgap generator (BG) 408a, 408b, and one or more low-drop regulators (LDO) 410a, 410b which provide internally regulated voltage supplies for a number of circuits that connect to the respective power grid 412a, 412b on each memory die. In general, each of primary memory die 130a and secondary die 130b is configured with the same components, although the orientation and/or arrangement may be different. In addition, each memory die can include a respective set of communication pads, which are not shown for simplicity. Various ones of the analog power components in each memory die can be connected to respective communication pads.

In one embodiment, one or more components in each of the memory dies 130a and 130b can be electrically shorted 295 to one another. For example, the communication pads to which those components are connected can be electrically shorted 295 to one another. In one embodiment, the low voltage and bandgap generator (BG) 408a, 408b in each memory die are electrically shorted 295 to one another and the low-drop regulators (LDO) 410a, 410b are electrically shorted 295 to one another. In this manner, external power supply signals, such as those received at the corresponding communication pad on primary die 130a from probe card 196, can be shared with the components on secondary die 130b. In one embodiment, the remainder of the respective power grids 412a, 412b on each memory die remain isolated from one another. For example, while each low-drop regulator (LDO) 410a, 410b may receive the same external power supply signal, each low-drop regulator (LDO) 410a, 410b can generate its own internal power supply signal that is provided to the corresponding power grid 412a, 412b on the same memory die. This arrangement prevents interference between the components of power grids 412a, 412b on the memory dies 130a and 130b.

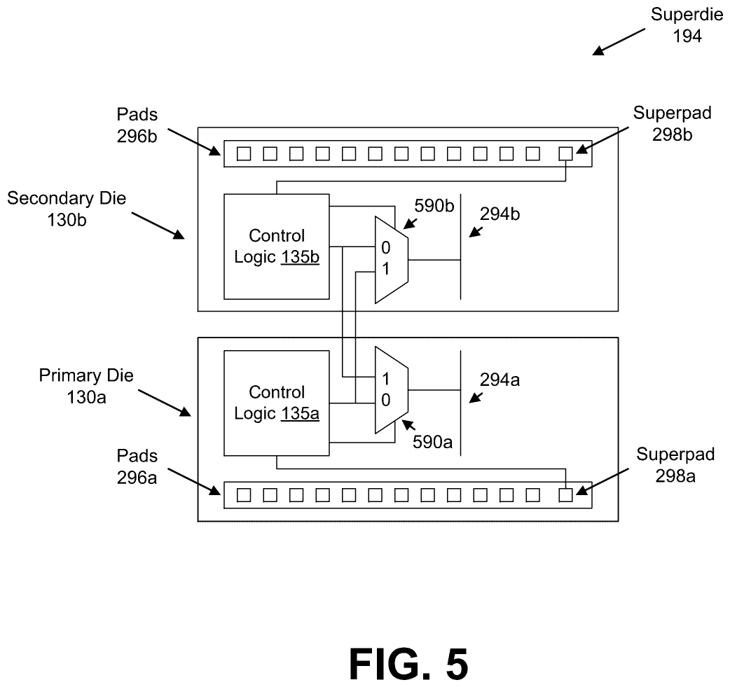

FIG. 5 is a block diagram illustrating switching of control signals in merged memory dies for wafer-level testing in accordance with some embodiments of the present disclosure. In one embodiment, primary memory die 130a and secondary memory die 130b have been at least temporarily merged to form superdie 194. As described above, each of primary memory die 130a and secondary memory die 130b includes a control logic component 135a, 135b, a set of signal communication pads 296a, 296b which provide an interface for transmitting signals between the components of each respective memory die and any off-chip circuitry, such as probe card 196, and potentially other components which are not shown. The control logic components 135a, 135b are configured to send control signals to those other components within each memory die over respective communication busses 294a, 294b.

In one embodiment, the communication busses 294a, 294b are electrically shorted together. For example, the communication pads to which the communication busses 294a, 294b are connected can be electrically shorted to one another. As noted above, the control logic component 135a remains active during testing and the control logic component 135b is deactivated during testing, so control logic component 135a can send control signals to the components on both memory dies 130a and 130b during testing. In general, the components on both memory dies 130a and 130b can receive the same control signals from control logic 135a during testing. The results of the testing, however, such as data read from each respective memory die during the testing, can be separated so that any errors associated with either of primary memory die 130a or secondary memory die 130b can be properly attributed. Since only one control logic component 135a is used, and the communication busses 294a, 294b are electrically shorted, the data read from each respective memory die can be transmitted in a time-staggered manner.

In one embodiment, each memory die includes a switching circuit 590a, 590b (e.g., a multiplexer). Each switching circuit 590a, 590b can receive an input signal from each of control logic components 135a, 135b and provide a respective output to the corresponding one of communication busses 294a, 294b based on a respective control signal. In one embodiment, each control signal is received from control logic components 135a, 135b and can be based on the corresponding superpad 298a, 298b. As described above, during testing in one embodiment, probe card 196 can apply a ground voltage signal to the superpad 298a on the primary memory die 130a (e.g., via one of micro-probes 198), while no signal is applied to the superpad 298b on the secondary memory die 130b. Accordingly, the voltage at superpad 298b is high (i.e., a logical ‘1’) and the voltage at superpad 298a is low (i.e., a logical ‘0’). With the inputs to switching circuit 590a, 590b connected as shown, the input signal from control logic 135a will be provided at the output of both switching circuits 590a, 590b. Since the signal from control logic 135a is connected to the ‘0’ input of switching circuit 590a and to the ‘1’ input of switching circuit 590b, the logical ‘0’ from superpad 298a and the logical ‘1’ from superpad 298b will select the signal from control logic 135a, which is provided to both communication busses 294a, 294b. Conversely, when probe card 196 applies a ground voltage signal to the superpad 298b on the secondary memory die 130b (e.g., via one of micro-probes 198), while no signal is applied to the superpad 298a on the primary memory die 130a, the voltage at superpad 298a is high (i.e., a logical ‘1’) and the voltage at superpad 298b is low (i.e., a logical ‘0’). With the inputs to switching circuit 590a, 590b connected as shown, the input signal from control logic 135b will be provided at the output of both switching circuits 590a, 590b. Since the signal from control logic 135b is connected to the ‘0’ input of switching circuit 590b and to the ‘1’ input of switching circuit 590a, the logical ‘0’ from superpad 298b and the logical ‘1’ from superpad 298a will select the signal from control logic 135b, which is provided to both communication busses 294a, 294b. It should be understood that the polarity would be reversed if a pull-down resistor 312 is used with superpads 298a and 298b instead of a pull-up resistor 302.

FIG. 6A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 6A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 6A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 6A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

FIG. 6B is a simplified block diagram of a first apparatus, in the form of a memory device 130, in communication with a second apparatus, in the form of a memory sub-system controller 115 of a memory sub-system (e.g., memory sub-system 110 of FIG. 6A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bit line). A single access line may be associated with more than one logical row of memory cells and a single data line may be associated with more than one logical column. Memory cells (not shown in FIG. 6B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In one embodiment, local media controller 135 includes corrective read module 134, which can implement the corrective read with partial block offset of memory device 130, as described herein.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 6B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 6B has been simplified. It should be recognized that the functionality of the various block components described with reference to FIG. 6B may not necessarily be segregated to distinct components or component portions of an integrated circuit device. For example, a single component or component portion of an integrated circuit device could be adapted to perform the functionality of more than one block component of FIG. 6B. Alternatively, one or more components or component portions of an integrated circuit device could be combined to perform the functionality of a single block component of FIG. 6B. Additionally, while specific I/O pins are described in accordance with popular conventions for receipt and output of the various signals, it is noted that other combinations or numbers of I/O pins (or other I/O node structures) may be used in the various embodiments.

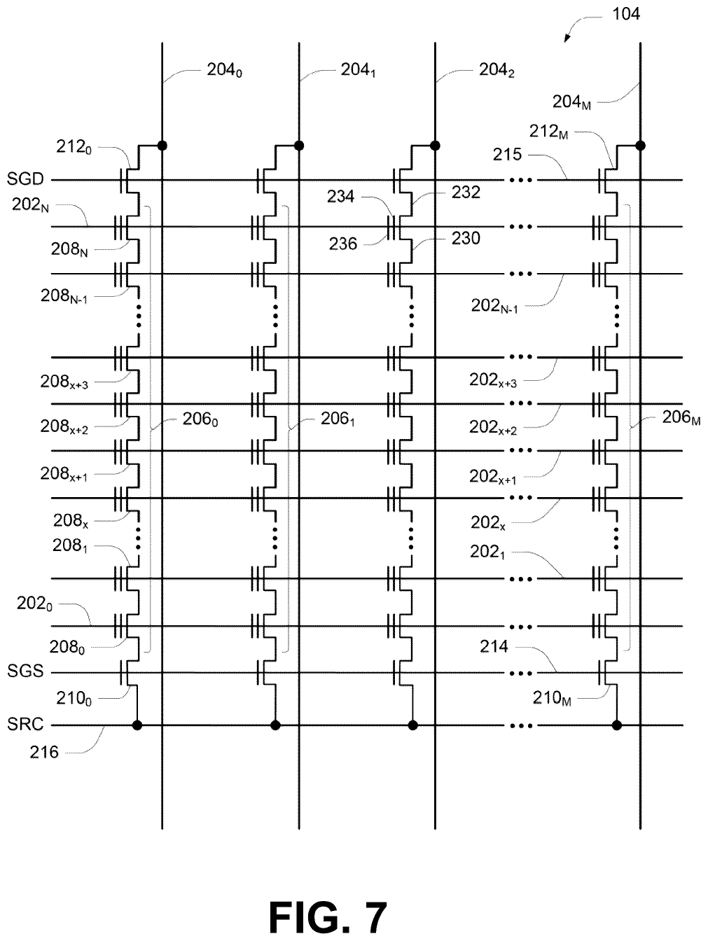

FIG. 7 is a schematic of portions of an array of memory cells 104, such as a NAND memory array, as could be used in a memory of the type described with reference to FIG. 6B according to an embodiment. Memory array 104 includes access lines, such as wordlines 202₀ to 202_{N}, and data lines, such as bit lines 204₀ to 204_{M}. The wordlines 202 can be connected to global access lines (e.g., global wordlines), not shown in FIG. 7, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 7 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 7. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 7, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 7 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

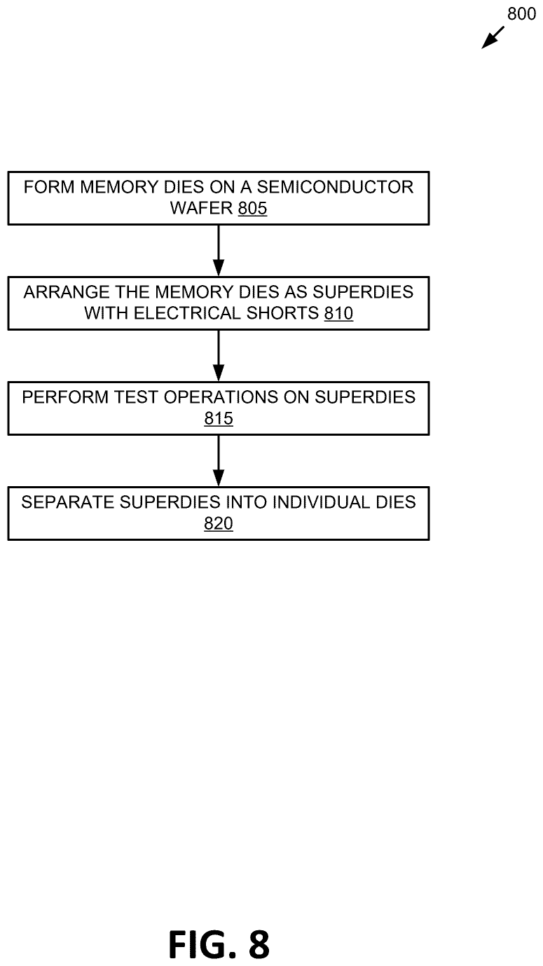

FIG. 8 is a flow diagram of an example method of forming merged memory dies for wafer-level testing in accordance with some embodiments of the present disclosure. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 805, memory dies are formed. In one embodiment, the processing logic (e.g., a semiconductor fabrication tool) can form a plurality of memory dies, such as memory dies 130, on a semiconductor wafer, such as wafer 190. In one embodiment, the memory dies are formed in a two-dimensional array including rows and columns of memory dies 130 on the wafer 190, with some amount of spacing therebetween. In one embodiment, the spacing between the memory dies in each column is less than the spacing between the memory dies in each row. In another embodiment, the spacing between the memory dies in each row is less than the spacing between the memory dies in each column.

At operation 810, superdies are formed. In one embodiment, the processing logic can arrange the plurality of memory dies 130 as a plurality of superdies, such as superdies 194, for testing. In one embodiment, each of the plurality of superdies 194 comprises two or more of the plurality of memory dies 130, such primary memory die 130a and secondary memory die 130b, for example. At least a subset of components of the two or more of the plurality of memory dies 130 in each of the plurality of superdies 194 are electrically shorted 295 together to receive shared test signals from test equipment during the testing.

At operation 815, the superdies are tested. In one embodiment, the processing logic (e.g., test equipment) can perform one or more test operations on the superdies 194. For example, the micro-probes 198 of a probe card 196 used to perform the testing may contact a set of communication pads 296a on primary memory die 130a to provide shared test signals. A set of communication pads 296b on secondary memory die 130b is not contacted by the micro-probes 198, which permits the spacing between adjacent memory dies that make up the superdie 194 to be reduced. Instead, the secondary memory die 130b can received the shared test signals from the primary memory die, such as via the electrical shorts 295.

At operation 820, the superdies are separated. In one embodiment, the processing logic (e.g., the semiconductor fabrication tool) can physically separate (e.g., cut) the individual memory dies 130 from the wafer 190. In one embodiment, the superdies 194 are separated from another while remaining intact. In another embodiment, the individual memory dies, such as primary memory die 130a and secondary memory die 130b, that make up a superdie 194 are physically separated from one another, such as by severing the electrical shorts 295 between the memory dies. In this manner, the individual memory dies 130 can be used in various implementations, such as in a memory sub-system 110.

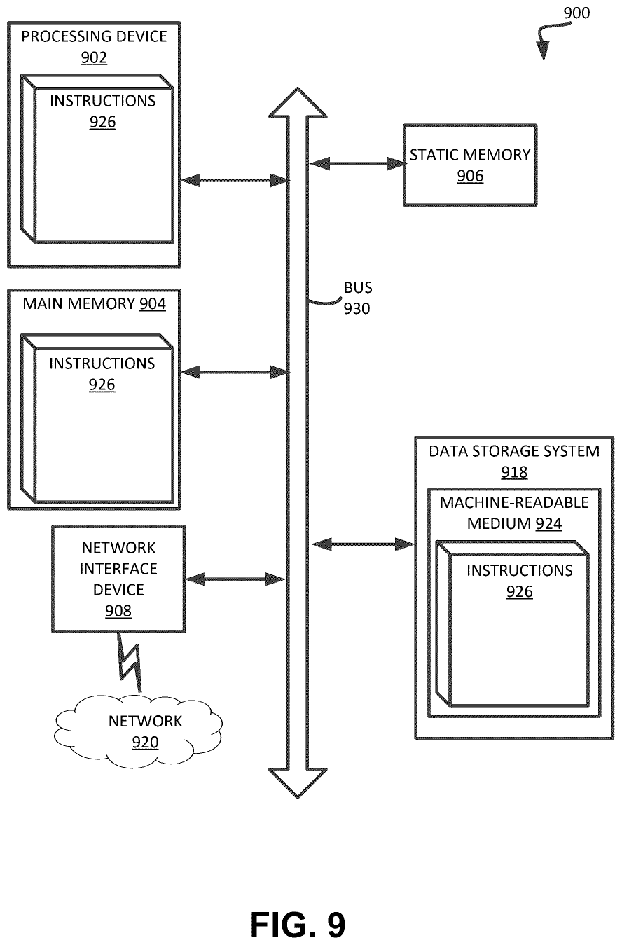

FIG. 9 illustrates an example machine of a computer system 900 within which a set of instructions, for causing the machine to perform any one or more of the methodologies discussed herein, can be executed. In some embodiments, the computer system 900 can correspond to a host system (e.g., the host system 120 of FIG. 6A) that includes, is coupled to, or utilizes a memory sub-system (e.g., the memory sub-system 110 of FIG. 6A) or can be used to perform the operations of a controller (e.g., to execute an operating system to perform operations corresponding to memory sub-system controller 115 or local media controller 135 of FIG. 6A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a data storage system 918, which communicate with each other via a bus 930.

Processing device 902 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 can also be one or more special-purpose processing devices such as an application specific integrated circuit (ASIC), a field programmable gate array (FPGA), a digital signal processor (DSP), network processor, or the like. The processing device 902 is configured to execute instructions 926 for performing the operations and steps discussed herein. The computer system 900 can further include a network interface device 908 to communicate over the network 920.

The data storage system 918 can include a machine-readable storage medium 924 (also known as a computer-readable medium) on which is stored one or more sets of instructions 926 or software embodying any one or more of the methodologies or functions described herein. The instructions 926 can also reside, completely or at least partially, within the main memory 904 and/or within the processing device 902 during execution thereof by the computer system 900, the main memory 904 and the processing device 902 also constituting machine-readable storage media. The machine-readable storage medium 924, data storage system 918, and/or main memory 904 can correspond to the memory sub-system 110 of FIG. 6A.

In one embodiment, the instructions 926 include instructions to implement functionality corresponding to the memory sub-system controller 115 or local media controller 135 of FIG. 6A. While the machine-readable storage medium 924 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a plurality of memory dies, wherein each memory die of the plurality of memory dies comprises:
a communication bus;
a memory array comprising a plurality of memory cells coupled with the communication bus;
a control logic component coupled with the communication bus;
an analog power component coupled with the communication bus and with the memory array; and
a plurality of signal communication pads coupled with the communication bus,
wherein one or more of the plurality of signal communication pads are electrically shorted with one or more signal communication pads on another memory die of the plurality of memory dies to share signals between the plurality of memory dies during testing of the memory device.

2. The memory device of claim 1, wherein one memory die of the plurality of memory dies is designated as a primary memory die and a remainder of the plurality of memory dies are designated as secondary memory dies.

3. The memory device of claim 2, wherein the control logic components of the secondary memory dies are disabled during the testing of the memory device, wherein control signals sent from the control logic component of the primary memory die control both the primary memory die and the secondary memory dies during the testing of the memory device, and wherein the control logic components of the secondary memory dies are tested separately in a subsequent testing operation.

4. The memory device of claim 2, wherein the plurality of signal communication pads comprises a superpad configured to receive a signal from an external testing device, the signal to indicate whether a corresponding memory die is the primary memory die or a secondary memory die.

5. The memory device of claim 4, wherein each memory die of the plurality of memory dies further comprises:
a pull-up resistor coupled between a voltage supply having a voltage supply level and a sampling node, wherein the superpad coupled to the sampling node, wherein when a ground voltage is applied to the superpad, the sampling node is at the ground voltage and an input buffer can decode the ground voltage at the sampling node as indicating that the memory die is the primary memory die, and wherein when no voltage is applied to the superpad, the sampling node is at the voltage supply level and the input buffer can decode the voltage supply level at the sampling node as indicating that the memory die is the secondary memory die.

6. The memory device of claim 4, wherein each memory die of the plurality of memory dies further comprises:
a pull-down resistor coupled between a ground voltage and a sampling node, wherein the superpad coupled to the sampling node, wherein when a voltage is applied to the superpad, the sampling node is at the voltage and an input buffer can decode the voltage at the sampling node as indicating that the memory die is the primary memory die, and wherein when no voltage is applied to the superpad, the sampling node is at the ground voltage and the input buffer can decode the ground voltage supply level at the sampling node as indicating that the memory die is the secondary memory die.

7. The memory device of claim 4, wherein each memory die of the plurality of memory dies comprises a switching circuit coupled to the control logic component of the primary memory die and to the control logic component of the secondary memory die, and wherein a control signal from the superpad controls the switching circuit via the control logic component to cause a data signal from the control logic component of the primary memory die to be transferred on the communication bus of the primary memory die and on the communication bus of the secondary memory die.

8. An apparatus comprising:
a semiconductor wafer; and
a plurality of memory dies disposed on the semiconductor wafer, wherein the plurality of memory dies are arranged as a plurality of superdies for testing, wherein each of the plurality of superdies comprises two or more of the plurality of memory dies, and wherein at least a subset of components of the two or more of the plurality of memory dies in each of the plurality of superdies are electrically shorted together to receive shared test signals from test equipment during the testing.

9. The apparatus of claim 8, wherein a first memory die of the two or more of the plurality of memory dies in each of the plurality of superdies is designated as a primary memory die and a second memory die of the two or more of the plurality of memory dies in each of the plurality of superdies is designated as a secondary memory die.

10. The apparatus of claim 9, wherein each of the plurality of memory dies comprises a control logic component, wherein the control logic component of the secondary memory die is disabled during the testing, and wherein control signals sent from the control logic component of the primary memory die control both the primary memory die and the secondary memory die during the testing.

11. The apparatus of claim 9, wherein each of the plurality of memory dies comprises a plurality of signal communication pads, and wherein the plurality of signal communication pads on the primary memory die is configured to be contacted by a set of micro-probes of the test equipment to receive the shared test signals.

12. The apparatus of claim 11, wherein the plurality of signal communication pads on the secondary memory die is not contacted by the set of micro-probes during the testing, and wherein the secondary memory die is to receive the shared test signals from the primary memory die.

13. The apparatus of claim 11, wherein the plurality of signal communication pads comprises a superpad configured to receive a signal from the test equipment, the signal to indicate whether a corresponding memory die is the primary memory die or the secondary memory die.

14. The apparatus of claim 8, wherein each of the plurality of memory dies comprises:
a communication bus;
a memory array comprising a plurality of memory cells coupled with the communication bus;
a control logic component coupled with the communication bus; and
an analog power component coupled with the communication bus.

15. A method comprising:
forming a plurality of memory dies on a semiconductor wafer; and
arranging the plurality of memory dies as a plurality of superdies for testing, wherein each of the plurality of superdies comprises two or more of the plurality of memory dies, and wherein at least a subset of components of the two or more of the plurality of memory dies in each of the plurality of superdies are electrically shorted together to receive shared test signals from test equipment during the testing.

16. The method of claim 15, wherein a first memory die of the two or more of the plurality of memory dies in each of the plurality of superdies is designated as a primary memory die and a second memory die of the two or more of the plurality of memory dies in each of the plurality of superdies is designated as a secondary memory die.

17. The method of claim 16, wherein each of the plurality of memory dies comprises a control logic component, wherein the control logic component of the secondary memory die is disabled during the testing, and wherein control signals sent from the control logic component of the primary memory die control both the primary memory die and the secondary memory die during the testing.

18. The method of claim 16, wherein each of the plurality of memory dies comprises a plurality of signal communication pads, and wherein the plurality of signal communication pads on the primary memory die is configured to be contacted by a set of micro-probes of the test equipment to receive the shared test signals.

19. The method of claim 18, wherein the plurality of signal communication pads on the secondary memory die is not contacted by the set of micro-probes during the testing, and wherein the secondary memory die is to receive the shared test signals from the primary memory die.

20. The method of claim 18, wherein the plurality of signal communication pads comprises a superpad configured to receive a signal from the test equipment, the signal to indicate whether a corresponding memory die is the primary memory die or the secondary memory die.
